(19) United States
(12) Patent Application Publication
(10) Pub. No.: US 2026/0332454 A1
(43) Pub. Date: Oct. 22, 2026

(54) BATTERY MANAGEMENT SYSTEM

(71) Applicant: Nuvoton Technology Corporation Japan, Kyoto (JP)

(72) Inventor: Hitoshi KOBAYASHI, Kyoto (JP)

(21) Appl. No.: 19/708,013

(22) Filed: Jun. 15, 2026

Related U.S. Application Data
(63) Continuation of application No. PCT/JP2024/041083, filed on Nov. 20, 2024.

(30) Foreign Application Priority Data
Dec. 19, 2023 (JP) 2023-214264

(51) Int. Cl. H04L 25/02; H01M 10/42; H01M 10/48; H04W 64/00

(52) U.S. Cl. CPC H04L 25/0212; H01M 10/425; H01M 10/48; H04W 64/006; H01M 2010/4271; H01M 2010/4278; H01M 2220/20

(57) ABSTRACT

A battery management system for managing a cell stack. The battery management system includes: a plurality of monitoring circuits that monitor the cell stack; and a management circuit that is connected to each of the plurality of monitoring circuits via wireless communication, and manages the cell stack. In the battery management system, at least one of the management circuit or each of the plurality of monitoring circuits includes a measurement circuit for measuring Time of Flight (TOF) between the management circuit and each of the plurality of monitoring circuits via impulse response ultra-wide band (IR-UWB) communication.

### CROSS REFERENCE TO RELATED APPLICATIONS

This is a continuation application of PCT International Patent Application No. PCT/JP 2024/041083 filed on Nov. 20, 2024, designating the United States of America, which is based on and claims priority of Japanese Patent Application No. 2023-214264 filed on Dec. 19, 2023. The entire disclosures of the above-identified applications, including the specifications, drawings and claims are incorporated herein by reference in their entirety.

### Field

The present disclosure relates to a battery management system for managing a cell stack.

### BACKGROUND

Patent Literature (PTL) 1 discloses a technique in which, in a battery management system, when a functional unit fails in wireless communication with a battery management unit, the functional unit changes the frequency of communication with the battery management unit and re-establishes a wireless communication connection with the battery management unit.

### CITATION LIST

### Patent Literature

PTL 1: US Patent Application Publication No. 2020/0083722

### SUMMARY

### Technical Problem

However, the technique disclosed by PTL 1 can be improved upon.

In view of this, the present disclosure provides a battery management system capable of improving upon the above related art.

### Solution to Problem

A battery management system according to the present disclosure is a battery management system for managing a cell stack. The battery management system includes: a plurality of monitoring circuits that monitor the cell stack; and a management circuit that is connected to each of the plurality of monitoring circuits via wireless communication, and manages the cell stack. In the battery management system, at least one of the management circuit or each of the plurality of monitoring circuits includes a measurement circuit for measuring Time of Flight (TOF) between the management circuit and each of the plurality of monitoring circuits via impulse response ultra-wide band (IR-UWB) communication.

Note that these generic and specific aspects may be implemented using a system, a method, an integrated circuit, a computer program, or a computer-readable recording medium such as a compact disc-read only memory (CD-ROM), and may also be implemented by any combination of systems, methods, integrated circuits, computer programs, and recording media.

### Advantageous Effects

According to one aspect of the present disclosure, it is possible to implement a battery management system capable of improving upon the above related art.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram schematically illustrating a vehicle provided with a battery management system according to Embodiment 1.

FIG. 2 is an external view illustrating one example of the battery management system according to Embodiment 1.

FIG. 3 is a configuration diagram illustrating one example of the battery management system according to Embodiment 1.

FIG. 4 is a diagram illustrating one example of a waveform of a state signal according to Embodiment 1.

FIG. 5 is a diagram illustrating frequency spectra of Bluetooth low energy (BLE) and ultra-wide band (UWB) according to Embodiment 1.

FIG. 6 is a schematic view illustrating transmission characteristics of radio waves of BLE and impulse response ultra-wide band (IR-UWB) according to Embodiment 1.

FIG. 7 is a flowchart illustrating an operation of a battery management system according to Embodiment 2.

FIG. 8 is a first diagram for explaining a Time of Flight (TOF) ranging method in the battery management system according to Embodiment 2.

FIG. 9 is a second diagram for explaining the TOF ranging method in the battery management system according to Embodiment 2.

FIG. 10A is one example of a table indicating distance information between a slave and a master according to Embodiment 2.

FIG. 10B is a diagram illustrating one example of a table in which a serial position and identification information of a monitoring circuit are associated with each other according to Embodiment 2.

FIG. 11 is a diagram illustrating one example of the placement example of the monitoring circuit according to Embodiment 2.

FIG. 12 is a configuration diagram illustrating one example of a battery management system according to a variation of Embodiment 2.

FIG. 13 is a diagram illustrating one example of the placement example of a monitoring circuit according to the variation of Embodiment 2.

FIG. 14A is one example of a table indicating distance information and angle information between a slave and a master according to the variation of Embodiment 2.

FIG. 14B is a diagram illustrating one example of a table in which a serial position and identification information of a monitoring circuit are associated with each other according to the variation of Embodiment 2.

FIG. 15 is a diagram schematically illustrating a vehicle provided with a battery management system according to Embodiment 3 and a terminal device.

FIG. 16 is a flowchart illustrating an operation of the battery management system according to Embodiment 3.

### DESCRIPTION OF EMBODIMENTS

Hereinafter, embodiments, etc. will be described in detail with reference to the Drawings.

Note that the embodiments described below each show a general or specific example. The numerical values, shapes, structural components, the arrangement and connection of the structural components, steps, the processing order of the steps, etc. shown in the following embodiments are mere examples, and therefore do not limit the scope of the claims of present disclosure. Among the structural components in the embodiments described below, those not recited in the independent claims will be described as optional structural components.

In addition, in this specification, terms indicating relationships between structural components, such as “same”, and numerical values and ranges, should not be construed as limited to their strict interpretation. Rather, they are intended to encompass substantially equivalent ranges, including variations of, for example, a few percent (or approximately 10 percent).

In addition, the term “above” (e.g., “above a battery pack”) applies not only when two structural components are spaced apart from each other with another structural component present between the two structural components, but also when the two structural components are in direct contact with each other.

In addition, in this specification, ordinal numbers such as “first” and “second” are used for the purpose of distinguishing between similar structural components to avoid confusion, and do not indicate the quantity or order of the structural components unless explicitly stated otherwise.

### Embodiment 1

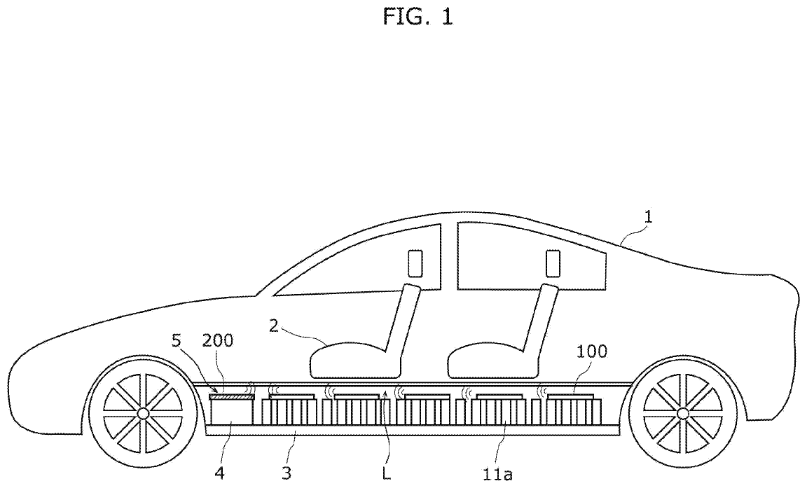

Hereinafter, a battery management system according to the present embodiment will be described with reference to FIG. 1 to FIG. 6.

In the technique disclosed in PTL 1, since only the frequency of communication with a battery management unit is changed, there is a possibility that a wireless communication connection cannot be re-established when the robustness of communication is low.

However, in a battery management system, there are instances where it is requested that units more reliably transmit intended information to each other using wireless communication. For example, there are instances where it is requested that a heartbeat or the like is more reliably transmitted using wireless communication.

In view of the above, the present embodiment will describe a battery management system in which units are capable of more reliably communicating wirelessly with each other within the battery management system.

### [1-1. Configuration of Battery Management System]

First, a configuration of a battery management system will be described with reference to FIG. 1 to FIG. 4. FIG. 1 is a diagram schematically illustrating vehicle 1 provided with battery management system 5 (hereinafter, also referred to as BMS 5) according to the present embodiment.

As illustrated in FIG. 1, BMS 5 is disposed below seats 2 of vehicle 1. Specifically, BMS 5 is disposed in a space (closed space) between seats 2 and chassis 3. The space is a small space. In other words, BMS 5 is disposed and used in the small space.

A cell stack including battery cells 11a, management circuit 200 that manages the cell stack, and monitoring circuits 100 that monitor the cell stack are disposed within the small space. Wireless communication is performed between management circuit 200 and each of monitoring circuits 100, and transmission channel L is formed within the small space. Management circuit 200 is connected to the cell stack via junction box 4.

Note that vehicle 1 is, for example, an electric vehicle. A non-limiting example of vehicle 1 is an electric vehicle (EV), and vehicle 1 may alternatively be an electric train or the like.

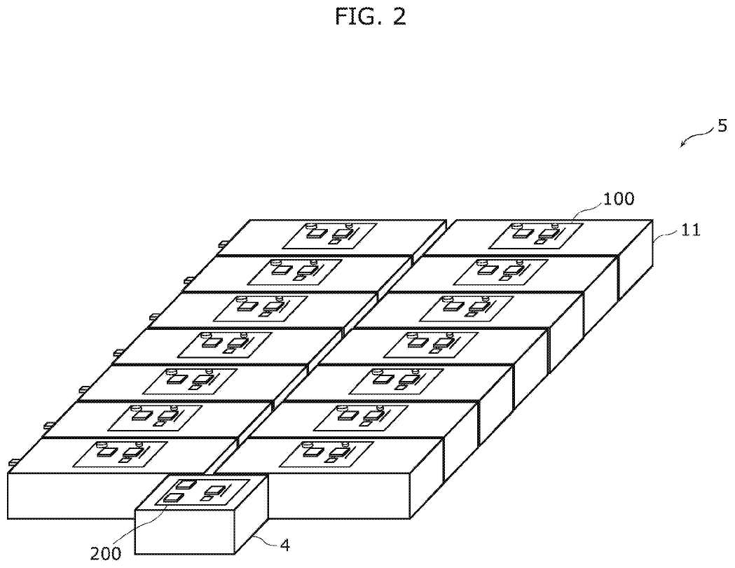

FIG. 2 is an external view illustrating one example of BMS 5 according to the present embodiment.

BMS 5 is a system for managing the cell stack. For example, BMS 5 manages the state of charge (SOC), state of health (SOH), state of power (SOP), etc. of the cell stack. In addition, BMS 5 monitors an anomaly in the cell stack. BMS 5 includes management circuit 200 that manages the cell stack and monitoring circuits 100 that monitor the cell stack. Moreover, BMS 5 may include another cell stack. For example, the cell stack is configured by connecting a plurality of battery packs 11 in series or parallel. Battery pack 11 includes one or more battery cells 11a. When battery pack 11 includes a plurality of battery cells 11a, the plurality of battery cells 11a are connected in series. Note that battery cell 11a is, for example, exemplified by, but is not limited to, a lithium-ion battery. In addition, for example, monitoring circuits 100 are respectively disposed above the plurality of battery packs 11.

Note that FIG. 2 illustrates an example in which management circuit 200 is disposed above junction box 4. However, the position at which management circuit 200 is disposed is not limited to the above-mentioned position. For example, management circuit 200 may be disposed inside junction box 4, and may be disposed on a side face of junction box 4. Likewise, FIG. 2 illustrates an example in which monitoring circuit 100 is disposed above battery pack 11. However, the position at which monitoring circuit 100 is disposed is not limited to the above-mentioned position. For example, monitoring circuit 100 may be disposed inside battery pack 11, and may be disposed on a side face of battery pack 11. As described above, the placement positions at which management circuit 200 and monitoring circuit 100 are disposed are not limited to the example illustrated in FIG. 2, and any placement position may be employed as long as they can communicate with each other.

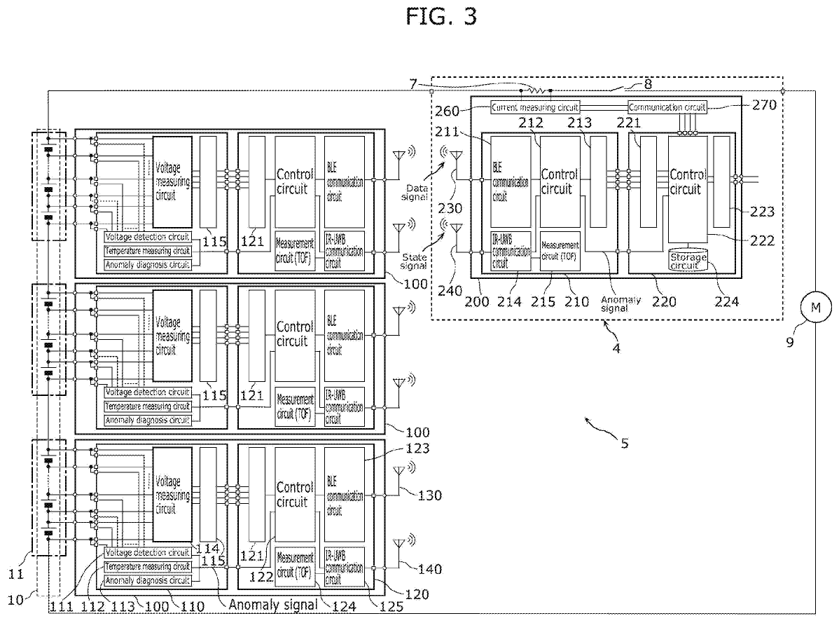

FIG. 3 is a configuration diagram illustrating one example of BMS 5 according to the present embodiment. Note that, in FIG. 3, three monitoring circuits 100 are illustrated; however, for convenience, the reference sign for each structural component included in monitoring circuit 100 are indicated only for monitoring circuit 100 located at the bottom of the drawing. For example, the three monitoring circuits 100 have the same configuration. In addition, the total number of monitoring circuits 100 included in BMS 5 is not particularly limited, and may be any as long as at least one monitoring circuit 100 is included.

As illustrated in FIG. 3, each of the plurality of monitoring circuits 100 includes battery monitor 110, wireless communication section 120, and communication antennas 130 and 140. In addition, in FIG. 3, junction box 4 is indicated by a dashed line. For example, battery monitor 110 and wireless communication section 120 are implemented respectively by different integrated circuit (IC), but they may be implemented by a single IC. As a specific example of monitoring circuit 100, for example, a cell management unit (CMU) is exemplified.

Battery monitor 110 has a function of monitoring cell stack 10, and includes voltage detection circuit 111, temperature measuring circuit 112, anomaly diagnosis circuit 113, voltage measuring circuit 114, and communication interface 115.

Voltage detection circuit 111 detects a voltage anomaly in battery cell 11a (see, for example, FIG. 1). When battery cell 11a is a lithium-ion battery, a usable voltage range is fixed. Voltage detection circuit 111 is configured to detect that the voltage has exceeded an upper limit of the usable voltage range of battery cell 11a, i.e., overvoltage, and that the voltage has fallen below a lower limit of the usable voltage range of battery cell 11a, i.e., undervoltage. Note that voltage detection circuit 111 need only be configured to be capable of detecting at least one of the overvoltage or the undervoltage.

For example, voltage detection circuit 111 may be configured to include comparators provided on a one-to-one basis to the plurality of battery cells 11a, and detect a voltage anomaly as a result of a voltage of battery cell 11a is compared to a predetermined voltage in the comparator.

Temperature measuring circuit 112 and anomaly diagnosis circuit 113 are circuits for detecting an anomaly (e.g., an anomaly in battery monitor 110) in monitoring circuit 100.

Temperature measuring circuit 112 is a circuit for temperature measurement for measuring a temperature of battery monitor 110. Temperature measuring circuit 112 includes a temperature sensor such as a thermistor, a thermocouple, etc.

Anomaly diagnosis circuit 113 is a circuit that diagnoses an anomaly state in battery monitor 110 (integrated circuit). Anomaly diagnosis circuit 113, for example, may diagnose an anomaly in battery monitor 110 by comparing a predetermined voltage in battery monitor 110 and a threshold, or may diagnose an anomaly in battery monitor 110 by using another method.

When an anomaly has been detected, voltage detection circuit 111, temperature measuring circuit 112, and anomaly diagnosis circuit 113 are configured to output an anomaly signal indicating that an anomaly has been detected, to wireless communication section 120 (specifically, control circuit 122).

Voltage measuring circuit 114 is a measuring circuit for measuring a voltage of each of the one or more battery cells 11a included in battery pack 11. A result of measuring a voltage by voltage measuring circuit 114 is output to wireless communication section 120 via communication interface 115.

Communication interface 115 is an interface for performing communications between wireless communication section 120 and battery monitor 110. Note that, when wireless communication section 120 and battery monitor 110 are implemented by a single IC, communication interface 115 need not necessarily be provided.

Note that monitoring circuit 100 may include, for example, a current monitoring unit (CMU) that measures a current flowing through cell stack 10.

Wireless communication section 120 and communication antennas 130 and 140 are structural components for monitoring circuit 100 to perform communication with management circuit 200.

Wireless communication section 120 is a wireless communication section (wireless communication IC) on the slave side in BMS 5, and includes communication interface 121, control circuit 122, Bluetooth low energy (BLE) communication circuit 123, measurement circuit 124, and impulse response ultra-wide band (IR-UWB) communication circuit 125.

Communication interface 121 is an interface for performing communications between wireless communication section 120 and battery monitor 110. Note that, when wireless communication section 120 and battery monitor 110 are implemented by a single IC, communication interface 121 need not necessarily be provided.

Control circuit 122 controls each of the structural components of wireless communication section 120. Control circuit 122 may, for example, transmit data obtained via communication interface 121, to management circuit 200 via BLE communication circuit 123 and communication antenna 130. In addition, for example, upon receiving an anomaly signal from any of voltage detection circuit 111, temperature measuring circuit 112, or anomaly diagnosis circuit 113, control circuit 122 may transmit a state signal indicating an anomaly, to management circuit 200 via IR-UWB communication circuit 125 and communication antenna 140. In addition, for example, when an anomaly signal is not obtained from any of voltage detection circuit 111, temperature measuring circuit 112, or anomaly diagnosis circuit 113, control circuit 122 may transmit a state signal indicating normality, to management circuit 200 via IR-UWB communication circuit 125 and communication antenna 140.

As described above, control circuit 122 transmits a signal related to a heartbeat to management circuit 200 via IR-UWB communication circuit 125, and transmits other signals (e.g., a data signal) to management circuit 200 via BLE communication circuit 123. Stated differently, control circuit 122 transmits a heartbeat using IR-UWB, and transmits information other than the heartbeat using a wireless communication standard other than IR-UWB.

BLE communication circuit 123 is a communication circuit that is connected to communication antenna 130 (one example of a second communication antenna), and is for transmitting to management circuit 200 a data signal including a measurement result (e.g., a voltage value) of the measurement performed in voltage measuring circuit 114, for example. BLE communication circuit 123 transmits the data signal to management circuit 200 via communication antenna 130.

BLE communication circuit 123 performs a communication using a wireless communication modulation scheme different from that of IR-UWB communication circuit 125. According to the present embodiment, BLE communication circuit 123 is configured to perform wireless communication in accordance with a BLE scheme. BLE communication circuit 123 performs a BLE communication with management circuit 200 (specifically, BLE communication circuit 211) using BLE. BLE communication circuit 123 is one example of a second wireless communication circuit. In addition, BLE communication circuit 123 is one example of another wireless communication section that monitoring circuit 100 includes.

Note that the modulation scheme is not limited to the BLE scheme, and may be, for example, a spread spectrum scheme, orthogonal frequency division multiplexing (OFDM) scheme, and the like. Furthermore, the modulation scheme used in BLE communication circuit 123 need not necessarily include an ultra-wide band (UWB) scheme (e.g., an IR-UWB scheme).

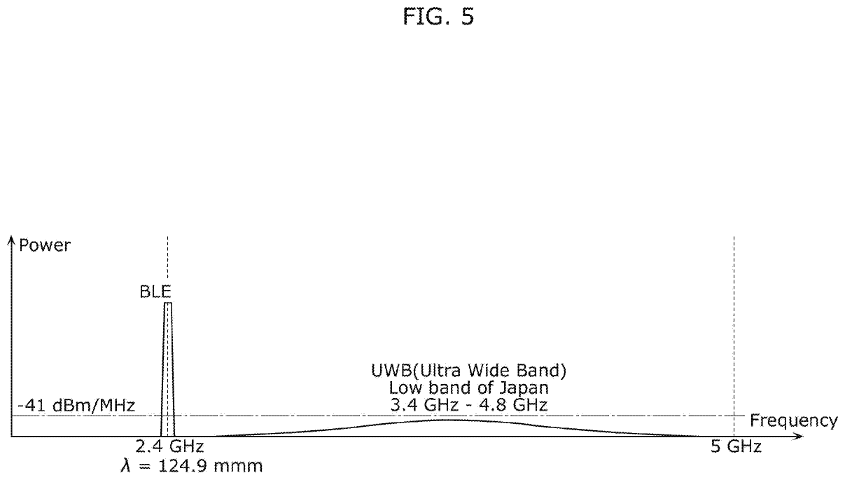

Note that the UWB scheme is a communication scheme in which power that is far lower than a noise level generated by a general electronic device or the like with a peak value of the transmission power of −41.3 dBm/MHz or less is spread over an extremely wide band to perform communication. This enables communication with low interference with other communications and low power consumption. In addition, in the case of the IR-UWB scheme that transmits a pulse signal including each component of UWB (for example, the 3.4 GHz to 4.8 GHz components indicated in FIG. 5 described later), the pulse signal is also referred to as an IR-UWB signal. The IR-UWB signal is, for example, a pulse signal including each frequency component of the UWB signals indicated in FIG. 5 described later.

Note that, in the description below, an example in which communication is performed using the IR-UWB scheme that is one example of the UWB scheme will be mainly described.

Measurement circuit 124 is a circuit for measuring Time of Flight (TOF) between monitoring circuit 100 and management circuit 200 via IR-UWB communication that is the communication of the IR-UWB scheme. The details of measurement circuit 124 will be described in Embodiment 2, etc. Note that, in the present embodiment, monitoring circuit 100 need not necessarily include measurement circuit 124.

IR-UWB communication circuit 125 is a communication circuit that is connected to communication antenna 140 (one example of the first communication antenna), and is for transmitting a state signal indicating an operation state of cell stack 10 or monitoring circuit 100 to management circuit 200. IR-UWB communication circuit 125 transmits a state signal to management circuit 200 via communication antenna 140. Note that IR-UWB communication circuit 125 does not transmit a data signal to management circuit 200 via communication antenna 140.

IR-UWB communication circuit 125 is configured to perform wireless communication in accordance with the UWB scheme. Stated differently, IR-UWB communication circuit 125 uses a signal of the UWB scheme (a UWB signal) for the state signal that transmits the operation state of cell stack 10 or monitoring circuit 100 to management circuit 200. According to the present embodiment, IR-UWB communication circuit 125 is configured to perform wireless communication in accordance with the IR-UWB scheme. In addition, IR-UWB communication circuit 125, for example, may broadcast-transmit a UWB signal. IR-UWB communication circuit 125 is one example of a UWB communication section included in monitoring circuit 100.

In addition, IR-UWB communication circuit 125 and BLE communication circuit 123 are examples of a plurality of wireless communication sections that are included in monitoring circuit 100, and use mutually different wireless communication modulation schemes.

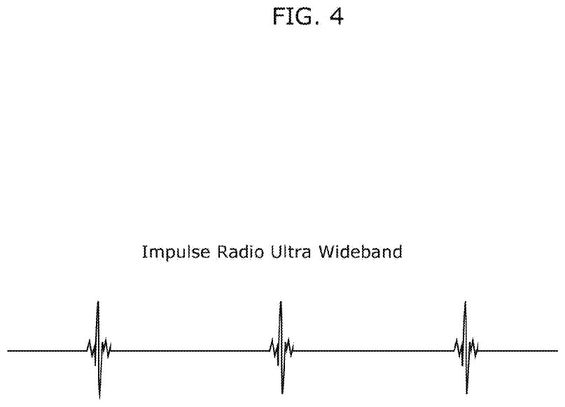

FIG. 4 is a diagram illustrating one example of waveforms of an IR-UWB signal according to the present embodiment.

IR-UWB communication circuit 125 transmits periodically an IR-UWB signal as illustrated in FIG. 4, as a state signal, to management circuit 200.

IR-UWB communication circuit 125 transmits the operation state of cell stack 10 or monitoring circuit 100 to management circuit 200 by, for example, changing the mode of the signal indicated in FIG. 4. IR-UWB communication circuit 125, for example, transmits an operation state by indicating any one of: presence or absence of impulse signals that are repeatedly transmitted, a change in a transmission time interval of the impulse signals, or a change in a repetition period of the impulse signals, but the mode of the state signal is not limited to this.

Note that the operation state includes whether cell stack 10 or monitoring circuit 100 is in a normal state or an anomaly state. The anomaly state in cell stack 10 includes at least one of the overvoltage or the undervoltage of cell stack 10. IR-UWB communication circuit 125 may, for example, transmit state signals of mutually different modes respectively in the normal state and the anomaly state. As described above, IR-UWB communication circuit 125 is configured to transmit a heartbeat in a form of a pulse signal to management circuit 200. IR-UWB communication circuit 125 is one example of a first wireless communication circuit.

Referring again to FIG. 3, management circuit 200 includes wireless communication section 210, micro controller unit (MCU) 220, communication antennas 230 and 240, current measuring circuit 260, communication circuit 270, shunt resistor 7, and relay 8. For example, wireless communication section 210 and MCU 220 are implemented by ICs different from each other, but may be implemented by a single IC. In addition, as a specific example of management circuit 200, for example, a battery management unit (BMU) is exemplified.

Wireless communication section 210 and communication antennas 230 and 240 are structural components for management circuit 200 to perform communication with monitoring circuit 100.

Wireless communication section 210 is a wireless communication section (wireless communication IC) on the master side in BMS 5, and includes BLE communication circuit 211, control circuit 212, communication interface 213, IR-UWB communication circuit 214, and measurement circuit 215.

BLE communication circuit 211 is a communication circuit that is connected to communication antenna 230 (one example a fourth communication antenna), and is for receiving a data signal from monitoring circuit 100. BLE communication circuit 211 receives a data signal from each of the plurality of monitoring circuits 100 via communication antenna 230.

BLE communication circuit 211 performs communication using a wireless communication modulation scheme different from that of IR-UWB communication circuit 214. According to the present embodiment, BLE communication circuit 211 is configured to perform wireless communication in accordance with a BLE scheme. BLE communication circuit 211 performs BLE communication with monitoring circuit 100 (specifically, BLE communication circuit 123) using BLE. BLE communication circuit 211 is one example of another wireless communication section that management circuit 200 includes.

Note that the modulation scheme is not limited to the BLE scheme, and may be, for example, a spread spectrum scheme, OFDM scheme, etc. Furthermore, the modulation scheme used in BLE communication circuit 211 need not necessarily include a UWB scheme (e.g., an IR-UWB scheme). BLE communication circuit 211 is one example of a fourth wireless communication circuit.

Control circuit 212 controls each of the structural components of wireless communication section 210. Control circuit 212 executes various processes, based on, for example, signals obtained by BLE communication circuit 211 and IR-UWB communication circuit 214. Control circuit 212 outputs the data signal obtained via BLE communication circuit 211, to control circuit 222 via communication interfaces 213 and 221. Furthermore, control circuit 212 outputs the state signal obtained via IR-UWB communication circuit 214 to control circuit 222.

In this manner, control circuit 212 receives the signal related to a heartbeat from each monitoring circuit 100 via IR-UWB communication circuit 214, and receives other signals (e.g., a data signal) from each monitoring circuit 100 via BLE communication circuit 211. Stated differently, control circuit 212 receives a heartbeat using IR-UWB, and receives information other than the heartbeat using a wireless communication standard other than IR-UWB.

Communication interface 213 is an interface for performing communication between wireless communication section 210 and MCU 220. Note that, when wireless communication section 210 and MCU 220 are implemented by a single IC, communication interface 213 need not necessarily be provided.

IR-UWB communication circuit 214 is a communication circuit that is connected to communication antenna 240 (one example of a third communication antenna), and is for receiving a state signal from each monitoring circuit 100.

IR-UWB communication circuit 214 is configured to perform wireless communication in accordance with the UWB scheme. Stated differently, IR-UWB communication circuit 214 receives a state signal from monitoring circuit 100 through the UWB scheme. According to the present embodiment, IR-UWB communication circuit 214 is configured to perform wireless communication in accordance with the IR-UWB scheme. IR-UWB communication circuit 214 performs IR-UWB communication with monitoring circuit 100 (specifically, IR-UWB communication circuit 125). IR-UWB communication circuit 214, for example, receives an IR-UWB signal as illustrated in FIG. 4 as a state signal from IR-UWB communication circuit 125. IR-UWB communication circuit 214 is one example of a third wireless communication circuit. In addition, IR-UWB communication circuit 214 is one example of a UWB communication section included in monitoring circuit 200.

In addition, IR-UWB communication circuit 214 and BLE communication circuit 211 are examples of a plurality of wireless communication sections that are included in management circuit 200, and use mutually different wireless communication modulation schemes.

Measurement circuit 215 is a circuit for measuring TOF between each of the plurality of monitoring circuits 100 and management circuit 200 via IR-UWB communication. The details of measurement circuit 215 will be described in Embodiment 2, etc. Note that, in the present embodiment, management circuit 200 need not necessarily include measurement circuit 215.

MCU 220 is a structural component for managing cell stack 10, and includes communication interface 221, control circuit 222, controller area network (CAN) interface 223, and storage circuit 224.

Communication interface 221 is an interface for performing communication between wireless communication section 210 and MCU 220. Note that, when wireless communication section 210 and MCU 220 are implemented by a single IC, communication interface 221 need not necessarily be provided.

Control circuit 222 controls each of the structural components of MCU 220. Control circuit 222 uses a first management table stored in storage circuit 224, to identify which position of battery cell 11a in which battery pack 11 the voltage value of battery cell 11a included in the data signal transmitted from monitoring circuit 100 corresponds to. The first management table, for example, is a table indicating a correspondence relationship between the position of battery pack 11 and identification information (e.g., identification information for use in BLE communication) of wireless communication section 120 included in monitoring circuit 100.

Furthermore, control circuit 222 uses a second management table stored in storage circuit 224, to identify in which monitoring circuit 100 the anomaly indicated by the state signal transmitted from monitoring circuit 100 is occurring.

CAN interface 223 is an interface for performing communication between MCU 220 and CAN. MCU 220 is connected to CAN via CAN interface 223.

Storage circuit 224 is a general or dedicated electric circuit in which information for performing information processes by control circuit 222 is stored Storage circuit 224 may be volatile memory or may be non-volatile memory. For example, the first management table and the second management table are stored in storage circuit 224.

Current measuring circuit 260 detects current flowing through cell stack 10. Current measuring circuit 260 is a current sensor of a resistance detection type that uses shunt resistor 7, but may be a current sensor of a field detection type. Current measuring circuit 260 may be configured to include an IC for current measurement.

Communication circuit 270 is a circuit that connects current measuring circuit 260 and control circuit 222 to be capable of communicating with each other.

Note that an example in which two types of modulation schemes are used for wireless communication between monitoring circuit 100 and management circuit 200 has been described above, but the present disclosure is not limited to this, and three or more types of modulation schemes may be used. In addition, of the two or more types of modulation schemes used for wireless communication between monitoring circuit 100 and management circuit 200, at least one includes the UWB scheme, and at least one includes a modulation scheme other than the UWB scheme.

In BMS 5 as described above, wireless communication is performed using the UWB scheme which is less susceptible to effects such as interference within BMS 5, and thus it is possible to enhance the robustness of communication within BMS 5. As a result, units are capable of more reliably transmitting information via wireless communication within BMS 5. For example, monitoring circuit 100 is capable of more reliably transmitting information to management circuit 200, using wireless communication.

Shunt resistor 7 is a current detection resistor for detecting current flowing through the series circuit of cell stack 10 and motor 9. Shunt resistor 7 is connected in series to cell stack 10. In the example illustrated in FIG. 3, shunt resistor 7 is connects between the positive electrode of cell stack 10 and motor 9. Note that a resistance value of shunt resistor 7 is not particularly limited.

Relay 8 is a switch for interrupting current flowing through a power line connecting cell stack 10 and motor 9. For example, relay 8 is turned off when current monitored by current measuring circuit 260 is determined to be anomalous, and interrupts the current flowing through the power line.

Motor 9 is one example of a load supplied with power from cell stack 10. Motor 9 is, for example, a drive motor for an electric vehicle. Cell stack 10 and motor 9 are connected via the power line. Note that the load is not limited to motor 9.

### [1-2. Characteristics of Various Signals]

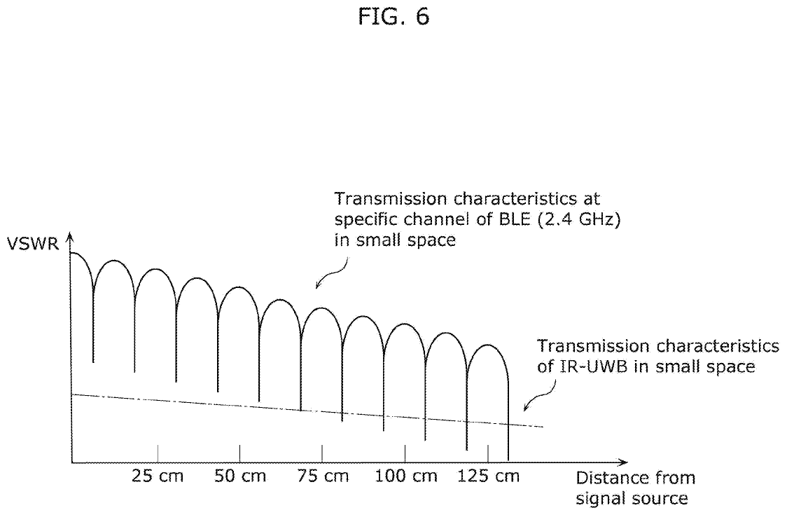

Next, various signals according to the present embodiment will be described with reference to FIG. FIG. 5 and FIG. 6. FIG. 5 is a diagram illustrating frequency spectra of BLE and UWB according to the present embodiment. In FIG. 5, the vertical axis indicates transmission power and the horizontal axis indicates frequency.

As illustrated in FIG. 5, the BLE signal is a signal with a peak at 2.4 GHz, whereas the UWB signal is a broad signal having a component in the wideband of 3.4 GHz to 4.8 GHz (low-band microwave range). The UWB signal, for example, does not include the peak frequency of the BLE signal, and includes frequency components higher than the peak frequency of the BLE signal. The transmission power of the peak frequency of the UWB signal is lower than the transmission power of the peak frequency of the BLE signal. When the IR-UWB signal is subjected to fast Fourier transform (FFT), it results in, for example, a wideband waveform of 3.4 GHz to 4.8 GHz as indicated in FIG. 5.

Note that the frequency band of the UWB signal is not limited to the example indicated in FIG. 5, and may be, for example, a band of 7.25 GHz to 10.25 GHz (high-band microwave range). In addition, as a frequency band of the UWB signal, a frequency band other than the frequency bands described above may be used depending on the country or region.

FIG. 6 is a schematic view illustrating transmission characteristics of radio waves of BLE and IR-UWB according to the present embodiment. In FIG. 6, the vertical axis indicates a voltage standing wave ratio (VSWR) and the horizontal axis indicates a distance from a signal source.

As illustrated in FIG. 6, the BLE signal at a specific channel in a small space has a characteristic in which the voltage standing wave ratio has antinodes and nodes depending on a distance. This characteristic is considered to be because, in a small space, standing waves arise and multipath occurs due to reflection of BLE signals. Furthermore, a BLE signal is susceptible to interference, and communication quality tends to deteriorate when there is an interfering wave at around 2.4 GHz. As a result, there is a possibility that a communication interruption or a communication error may occur with BLE signals.

On the other hand, the IR-UWB signal is a signal having a wideband component as indicated in FIG. 5, and thus the IR-UWB signal has a characteristic of a gradual downward slope to the right compared to the BLE signal (a characteristic in which antinodes and nodes are less likely to form in the voltage standing wave ratio). Furthermore, the IR-UWB signal is less susceptible to interference, and the communication quality is less likely to deteriorate even if, for example, there is an interfering wave of a specific frequency. In other words, with the IR-UWB signal, it is possible to reduce the arising of standing waves and the occurrence of multipath.

As a result, even if the BLE communication is interrupted, the IR-UWB communication can continue communication without interruption. For example, in BMS 5, even if the BLE communication is interrupted, it is possible to transmit a heartbeat to management circuit 200 via the IR-UWB communication. As a result, it is possible to more reliably transmit a heartbeat to management circuit 200.

As described above, in BMS 5, signals having mutually different transmission characteristics are used for communication between BLE communication circuits 123 and 211 and communication between IR-UWB communication circuits 125 and 214. According to the present embodiment, a signal having a transmission characteristic different from a transmission characteristic of the IR-UWB signal is used for communication between BLE communication circuits 123 and 211.

Note that an example in which a signal indicating a heartbeat is transmitted to management circuit 200 using the IR-UWB communication has been described above, but a signal indicating other information may be transmitted to management circuit 200 using the IR-UWB communication. The other information includes, for example, binary information related to cell stack 10 or monitoring circuit 100 (e.g., normal/anomalous, ON/OFF, etc.).

### Embodiment 2

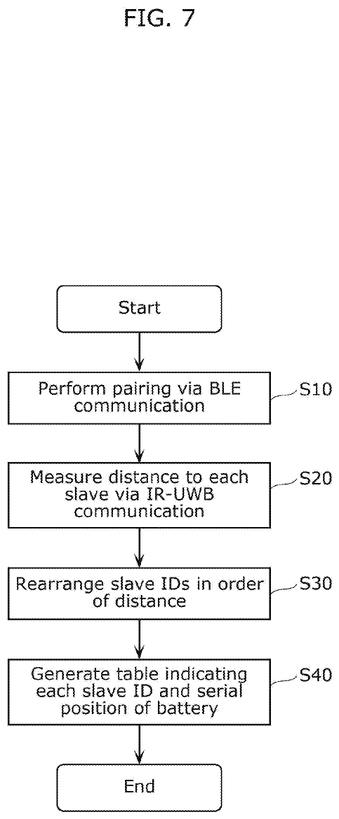

Hereinafter, a battery management system (BMS) according to the present embodiment will be described with reference to FIG. 7 to FIG. 11. Note that the following description focuses on the differences from Embodiment 1; explanations regarding points that are identical or similar to Embodiment 1 will be omitted or simplified. Each structural component of the BMS according to the present embodiment may be identical to those of BMS 5 according to Embodiment 1, and the reference signs used in Embodiment 1 will be used for describing the respective structural components in the following description.

As described in Embodiment 1, cell stack 10 includes a plurality of battery packs 11, and monitoring circuits 100 are provided one-to-one to the plurality of battery packs 11. Management circuit 200 obtains data such as a voltage value of each battery cell 11a from each monitoring circuit 100. However, in order to manage the data, information indicating the position at which battery pack 11 (or battery cell 11a) to which the data pertains is disposed. In other words, information indicating a correspondence relationship between battery pack 11 (or battery cell 11a) and monitoring circuit 100.

It is also possible for a worker or the like to generate a table indicating the correspondence relationship between battery pack 11 and monitoring circuit 100 and store the table in management circuit 200. However, this is time-consuming. In view of the above, the present embodiment describes a BMS capable of automatically generating such a table.

### [2-1. Operation of Battery Management System]

First, an operation of the BMS according to the present embodiment will be described with reference to FIG. FIG. 7 to FIG. 10B. FIG. 7 is a flowchart indicating the operation (control method) of the BMS according to the present embodiment. The operation indicated in FIG. 7 is, for example, executed after monitoring circuit 100 is disposed on each battery pack 11.

As illustrated in FIG. 7, first, the BMS performs pairing via BLE communication (S10). In step S10, control circuit 222 performs pairing between BLE communication circuit 123 of each of the plurality of monitoring circuits 100 and BLE communication circuit 211 of management circuit 200 via BLE communication. This pairing enables control circuit 222 to obtain slave ID (identification information) of each monitoring circuit 100.

The identification information may be information that is used by BLE communication circuit 123 in monitoring circuit 100. The identification information, for example, may be information that is used in BLE communication between BLE communication circuits 123 and 211 in monitoring circuit 100. For example, the identification information may be a media access control (MAC) address of each monitoring circuit 100, may be an internal protocol (IP) address, or may be other information unique to each monitoring circuit 100. Control circuit 222 stores identification information (pairing information) of each monitoring circuit 100 obtained through pairing, in storage circuit 224.

Note that, at this point, the placement position of each monitoring circuit 100 has not been identified. In addition, control circuit 222 may calculate a distance to each monitoring circuit 100 via BLE communication in step S10.

Next, the BMS measures a distance to each slave (each monitoring circuit 100) via IR-UWB communication (S20). In step S20, control circuit 222 measures a distance between each monitoring circuit 100 and management circuit 200. Control circuit 222 measures TOF between each monitoring circuit 100 and management circuit 200 via IR-UWB communication, thereby calculating the distance between each monitoring circuit 100 and management circuit 200.

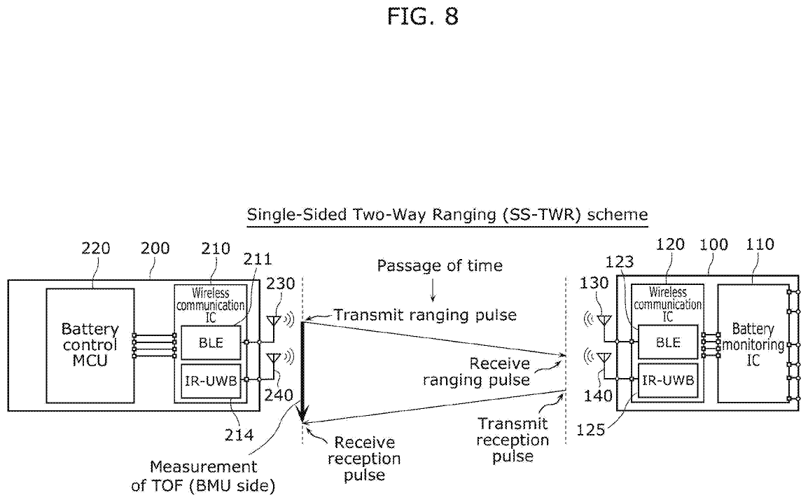

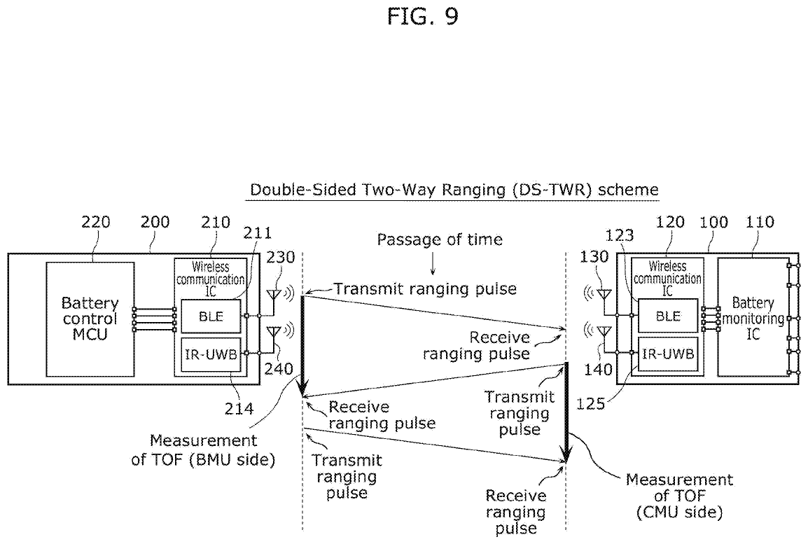

FIG. 8 and FIG. 9 are each a diagram for explaining a TOF ranging method in the BMS according to the present embodiment. Either of the TOF ranging methods indicated in FIG. 8 and FIG. 9 may be used. However, from the viewpoint of measurement accuracy, the method indicated in FIG. 9 may be used.

Note that, in FIG. 8 and FIG. 9, the configurations of monitoring circuit 100 and management circuit 200 are illustrated in a simplified manner. In addition, in FIG. 8 and FIG. 9, for convenience, BLE communication circuits 123 and 211 are each denoted as “BLE”, IR-UWB communication circuits 125 and 214 are each denoted as “IR-UWB”, wireless communication sections 120 and 210 are each denoted as “wireless communication IC”, battery monitor 110 is denoted as “battery monitoring IC”, and MCU 220 is denoted as “battery control MCU”. Furthermore, ranging pulse signals and reception pulse signal are each an IR-UWB signal. In addition, in FIG. 8 and FIG. 9, the direction from top to bottom on the diagram indicates the passage of time.

FIG. 8 illustrates a single-sided two-way ranging (SS-TWR) scheme that is a scheme to perform the measurement of TOF on the management circuit 200 side (BMC side).

In this case, IR-UWB communication circuit 214 of management circuit 200 transmits a ranging pulse signal via communication antenna 240. IR-UWB communication circuit 125 of monitoring circuit 100 receives the ranging pulse signal transmitted from management circuit 200, and transmits a reception pulse signal indicating that the ranging pulse signal has been received to management circuit 200 via communication antenna 140. IR-UWB communication circuit 214 of management circuit 200 receives the reception pulse signal transmitted from monitoring circuit 100. Measurement circuit 215 measures a time period from when the ranging pulse signal has been transmitted to when the reception pulse signal has been received as TOF. In other words, measurement circuit 215 measures TOF between monitoring circuit 100 and management circuit 200 via IR-UWB communication (see the bold arrow indicated in FIG. 8).

Note that, in the case of the scheme illustrated in FIG. 8, monitoring circuit 100 need not necessarily include measurement circuit 124.

FIG. 9 illustrates a double-sided two-way ranging (DS-TWR) that is a scheme to perform the measurement of TOF on both the monitoring circuit 100 side (CMU side) and the management circuit 200 side (BMU side).

In this case, IR-UWB communication circuit 214 of management circuit 200 transmits a ranging pulse signal (first ranging pulse signal) via communication antenna 240. IR-UWB communication circuit 125 of monitoring circuit 100 receives the first ranging pulse signal transmitted from management circuit 200, and transmits a ranging pulse signal (second ranging pulse signal) in response to receiving the first ranging pulse signal to management circuit 200 via communication antenna 140. IR-UWB communication circuit 214 of management circuit 200 receives the second reception pulse signal transmitted from monitoring circuit 100. Measurement circuit 215 measures a time period from when the first ranging pulse signal has been transmitted to when the second reception pulse signal has been received as TOF (see the bold arrow indicated on the management circuit 200 side in FIG. 9).

Furthermore, IR-UWB communication circuit 214 of management circuit 200 transmits a ranging pulse signal (third ranging pulse signal) in response to receiving the second ranging pulse signal transmitted from monitoring circuit 100, to monitoring circuit 100 via communication antenna 240. IR-UWB communication circuit 125 of monitoring circuit 100 receives the third reception pulse signal transmitted from management circuit 200. Measurement circuit 124 measures a time period from when the second ranging pulse signal has been transmitted to when the third reception pulse signal has been received as TOF (see the bold arrow indicated on the monitoring circuit 100 side in FIG. 9).

TOF measured by measurement circuit 124 may be, for example, transmitted to management circuit 200 via BLE communication.

The measurement of TOF according to the schemes indicated in FIG. 8 and FIG. 9 is performed sequentially by each monitoring circuit 100. Management circuit 200, for example, transmits identification information of monitoring circuit 100 which performs the measurement of TOF, using BLE communication to each monitoring circuit 100. As a result, only monitoring circuit 100 which performs the measurement of TOF can reply a signal to the ranging pulse from management circuit 200.

Control circuit 222 calculates a distance between each monitoring circuit 100 and management circuit 200, based on TOF measured according to the scheme indicated in FIG. 8 or FIG. 9. Control circuit 222 may associate at least one of TOF that has been obtained or the distance calculated based on TOF with the identification information of monitoring circuit 100, and store it in storage circuit 224.

Referring again to FIG. 7, next, control circuit 222 rearranges slave IDs in order of distance (S30). Control circuit 222 rearranges items of identification information of monitoring circuits 100 obtained in step S10, in order of distance measured in step S20. In this manner, the items of identification information of monitoring circuits 100 are arranged in line, for example, in order of proximity to management circuit 200.

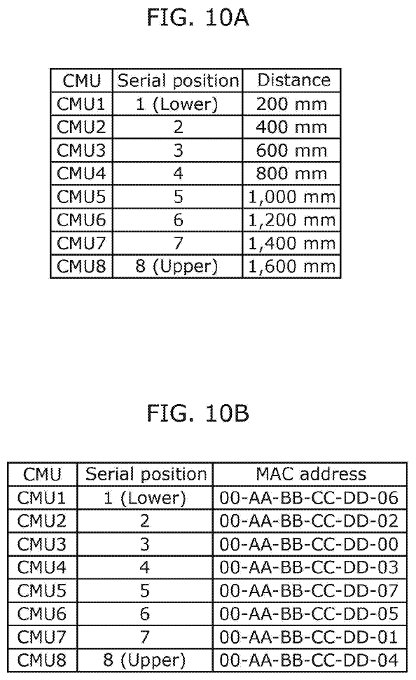

FIG. 10A is a diagram illustrating an example of a table (first table) indicating distance information between a slave and a master according to the present embodiment. The table illustrated in FIG. 10A is obtained before step S10 is executed; for example, before monitoring circuit 100 is disposed on cell stack 10, and is stored in storage circuit 224. The table illustrated in FIG. 10A is one example of a positional information database.

As illustrated in FIG. 10A, the table includes CMU, serial position, and distance as items.

CMU indicates a virtual address of a placement position of monitoring circuit 100 assigned in management circuit 200.

The serial position is information indicating a relative positional relationship of distance from management circuit 200, and is configured by arranging eight items in a column from “1 (Lower)” that is closest to management circuit 200 to “8 (Upper)” that is farthest from management circuit 200. The serial position is one example of the positional information indicating the relative relationship of the positions at which the plurality of monitoring circuits 100 are arranged.

Note that the information indicating battery pack 11 (or battery cell 11a) for a corresponding one of the serial positions is obtained in advance and stored in storage circuit 224. In other words, if it is known at which serial position monitoring circuit 100 is disposed, control circuit 222 can identify which battery pack 11 the data signal from monitoring circuit 100 has measured.

Distance indicates a distance specified based on a position at which monitoring circuit 100 can be physically disposed and a position of management circuit 200 in the BMS. The distance can be obtained, for example, at a design stage of the BMS. In other words, the distance is obtained before a point in time when monitoring circuit 100 is disposed in cell stack 10.

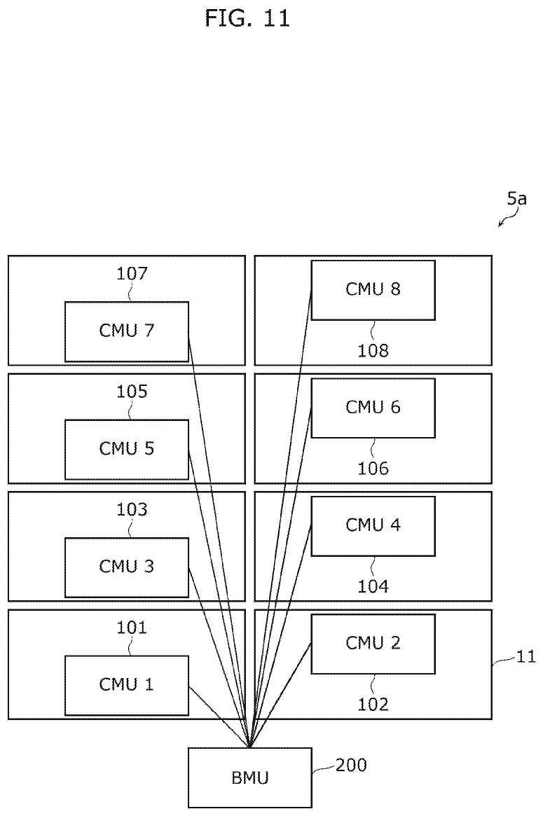

According to the present embodiment, the design is such that monitoring circuit 100 is disposed at intervals of 200 mm from management circuit 200. The placement example of monitoring circuit 100 will be described later with reference to FIG. 11.

As described above, the table illustrated in FIG. 10A is a table in which a distance between management circuit 200 and a position at which each of the plurality of monitoring circuits 100 is disposed and positional information indicating the relative relationship between positions at which the plurality of monitoring circuits 100 are disposed are associated with each other.

The table illustrated in FIG. 10A indicates an example in which, in the BMS, monitoring circuits 100 are disposed such that distances to management circuit 200 differ from one another. Note that monitoring circuits 100 are not limited to being disposed such that distances to management circuit 200 differ from one another. At least two monitoring circuits 100 may be disposed such that distances to management circuit 200 are equal to each other. “Equal” here includes not only the cases where distances completely match, but also the cases where there is a distance error (for example, approximately several percent or approximately 10%) according to the measurement accuracy of measurement performed by measuring circuit 215 or the like.

Control circuit 222 may, for example, determine, using the table indicated in FIG. 10A, whether the distance measured in step S20 is within a predetermined range. Control circuit 222, for example, arranges the items of identification information of monitoring circuits 100 in order of proximity to management circuit 200, determines whether the distance to the closest monitoring circuit 100 is within a predetermined range including 200 mm, and determines whether the distance to the next closest monitoring circuit 100 is within a predetermined range including 400 mm. Control circuit 222 performs this determination for each monitoring circuit 100. When there is monitoring circuit 100 that is outside the predetermined range, there is a possibility that distance measurement has failed, and thus control circuit 222 may perform distance measurement again for monitoring circuit 100 that is outside the predetermined range.

Next, control circuit 222 generates a table (second table) indicating each slave ID and a serial position of a battery (S40). Control circuit 222 generates a second table based on the table indicating the distance information between a slave and a master (the table illustrated in FIG. 10A) and the items of identification information of monitoring circuits 100 that have been rearranged in step S30.

FIG. 10B is a diagram illustrating one example of the table (second table) in which a serial position and identification information of monitoring circuit 100 are associated with each other, according to the present embodiment. In the example of FIG. 10B, a MAC address is included as the identification information of monitoring circuit 100.

As illustrated in FIG. 10B, according to the present embodiment, control circuit 222 generates a table in which a serial position and a MAC address of monitoring circuit 100 are associated with each other.

Control circuit 222 generates the table illustrated in FIG. 10B, by associating one to one the serial positions indicated in FIG. 10A and the items of identification information of monitoring circuits 100 that have been rearranged in order of distance. When the items of identification information of monitoring circuits 100 are rearranged in order of proximity, control circuit 222 associates the serial position “1 (Lower)” with the identification information positioned at the top (i.e., identification information of monitoring circuit 100 with the smallest distance). Next, control circuit 222 associates the serial position “2” with the identification information positioned at the second from the top (i.e., identification information of monitoring circuit 100 with the second smallest distance).

As described above, control circuit 222 generates the table illustrated in FIG. 10B, by sequentially associating the serial position with the identification information of monitoring circuit 100.

Note that the generating of the table illustrated in FIG. 10B corresponds to associating the identification information of each monitoring circuit 100 with the position of corresponding battery pack 11 (or battery cell 11a).

Note that the order of arrangement of the MAC addresses (one example of the items of identification information) illustrated in FIG. 10B matches the order of arrangement of the MAC addresses of monitoring circuits 100 rearranged in step S30.

Control circuit 222 stores, in storage circuit 224, the table (second table) that has been generated in step S40.

Here, the placement example of monitoring circuit 100 in BMS 5a according to the present embodiment will be described with reference to FIG. 11. FIG. 11 is a diagram illustrating one example of the placement example of monitoring circuit 100 according to the present embodiment. FIG. 11 illustrates the placement example when eight monitoring circuits, namely, monitoring circuits 101 to 108 (CMU 1 to CMU 8), are viewed from above.

As illustrated in FIG. 11, in BMS 5a according to the present embodiment, monitoring circuits 100 are arranged at mutually different distances from management circuit 200. Monitoring circuits 100 are arranged, for example, in a zig-zag pattern when viewed from above. With this configuration, since there is no monitoring circuit 100 at an equal distance, it is possible to identify the placement position of monitoring circuit 100 by measuring only a distance.

In the case of FIG. 11, the serial position “1 (Lower)” is associated with the identification information of monitoring circuit 101, the serial position “2” is associated with the identification information of monitoring circuit 102, the serial position “3” is associated with the identification information of monitoring circuit 103, and the serial position “4” is associated with the identification information of monitoring circuit 104. Furthermore, the serial position “5” is associated with the identification information of monitoring circuit 105, the serial position “6” is associated with the identification information of monitoring circuit 106, the serial position “7” is associated with the identification information of monitoring circuit 107, and the serial position “8 (Upper)” is associated with the identification information of monitoring circuit 108.

Note that, in FIG. 11, monitoring circuits 100 are aligned in up-down direction of the diagram in two columns positioned side by side, but may be, for example, aligned in a single column, or aligned in three or more columns positioned side by side.

### Variation of Embodiment 2

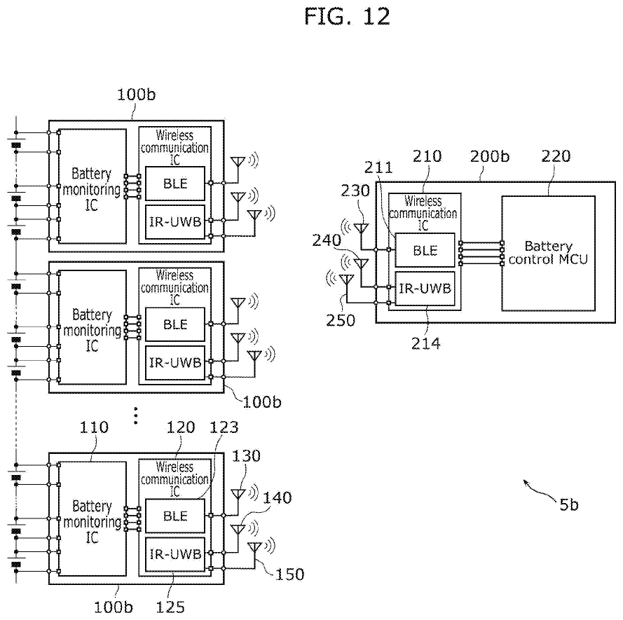

The following describes a battery management system (BMS) according to the present variation with reference to FIG. 12 to FIG. 14B. Note that the following description focuses on the differences from Embodiment 2, and explanations regarding points that are identical or similar to Embodiment 2 will be omitted or simplified.

FIG. 12 is a configuration diagram illustrating one example of BMS 5b according to the present variation. BMS 5b according to the present variation differs from BMS 5a according to Embodiment 2 in that communication antennas 150 and 250 are included. Note that, in FIG. 12, battery monitor 110, wireless communication sections 120 and 210, and MCU 220 are illustrated in schematic configurations.

As illustrated in FIG. 12, monitoring circuit 100b includes, as communication antenna connected to IR-UWB communication circuit 125, communication antenna 150 in addition to communication antenna 140. Management circuit 200b includes, as communication antenna connected to IR-UWB communication circuit 214, communication antenna 250 in addition to communication antenna 240.

Communication antennas 240 and 250 are used for measuring the distance between each monitoring circuit 100b and management circuit 200b, using IR-UWB communication. As described above, management circuit 200b includes a plurality of communication antennas for IR-UWB communication.

Communication antennas 140 and 150 are used for measuring the distance between monitoring circuit 100b and management circuit 200b, using IR-UWB communication. More specifically, communication antenna 140 is used when management circuit 200b measures the distance using communication antenna 240 via IR-UWB communication, and communication antenna 150 is used when management circuit 200b measures the distance using communication antenna 250 via IR-UWB communication. As described above, management circuit 100b includes a plurality of communication antennas for IR-UWB communication. Note that, when communication antennas 240 and 250, for example, transmits IR-UWB signals using time division, monitoring circuit 100b only need to include one of communication antenna 140 or communication antenna 150.

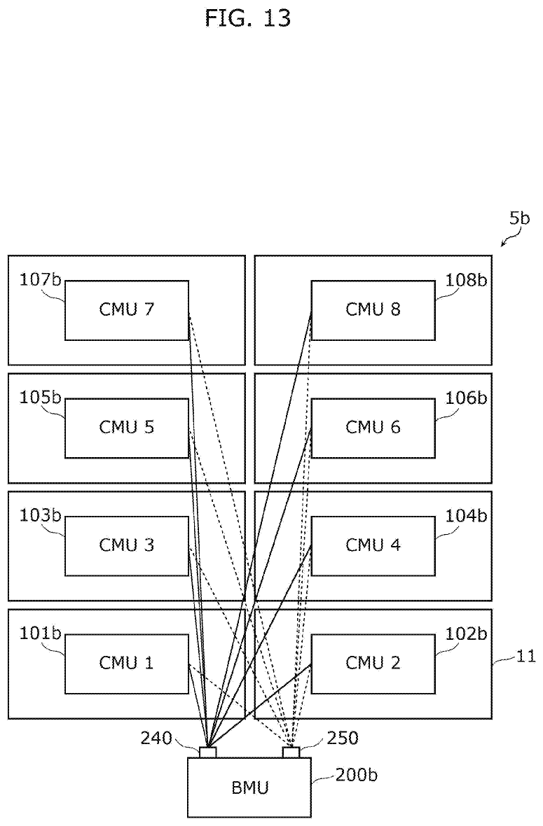

FIG. 13 is a diagram illustrating an example of the placement example of monitoring circuit 100b according to the present variation. Monitoring circuits 101b and 102b illustrated in FIG. 13 are located at an equal distance from management circuit 200b. Likewise, monitoring circuits 103b and 104b, monitoring circuits 105b and 106b, and monitoring circuits 107b and 108b are also located at equal distances from management circuit 200b.

As described above, in the present variation, among monitoring circuits 100b, at least two monitoring circuits 100b are located at an equal distance from management circuit 200b.

As illustrated in FIG. 13, communication antennas 240 and 250 are arranged at positions at different distances from each of monitoring circuits 101b to 108b. Communication antennas 240 and 250, for example, are arranged at a predetermined interval. Communication antennas 240 and 250, for example, are arranged side by side in a direction parallel to the direction in which monitoring circuits 101b and 102b which are arranged at an equal distance from management circuit 200b are aligned. Communication antennas 240 and 250 are arranged at positions where the straight line connecting communication antenna 240 and one of monitoring circuits 100b and the dashed line connecting communication antenna 250 and the one of monitoring circuits 100b are not in parallel. In this manner, using trigonometry, it is possible to obtain an angle (relative angle) between management circuit 200b and monitoring circuit 100b. This angle is, for example, an angle formed between the direction in which CMUs 1, 3, 5, and 7 are arranged (the up-down direction of the diagram) and a line segment connecting monitoring circuit 100b and management circuit 200b. The angle is, for example, less than or equal to 90 degrees.

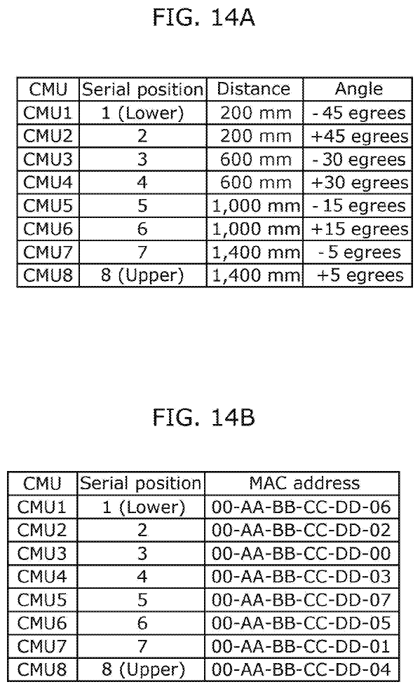

FIG. 14A is one example of a table indicating a distance and angle information between a slave and a master according to the present variation. The table illustrated in FIG. 14A is obtained before step S10 illustrated in FIG. 7 is executed; for example, before monitoring circuit 100b is disposed on cell stack 10, and is stored in storage circuit 224. The table illustrated in FIG. 14A is one example of a positional information database.

As illustrated in FIG. 14A, the table includes CMU, serial position, distance, and angle as items.

The angle is an angle formed between the up-down direction of the diagram and a line segment connecting monitoring circuit 100b and management circuit 200b in the case of FIG. 13. In addition, the angle between management circuit 200b and monitoring circuit 100b disposed in each of CMUs 2, 4, 6, and 8 is calculated, for example, as a positive angle, and the angle between management circuit 200b and each of CMUs 1, 3, 5, and 7 is calculated, for example, as a negative angle.

In the present variation, as illustrated in FIG. 13, two monitoring circuits 100 b are positioned at 400 mm intervals starting from a position distant by 200 mm from 200b. By using the angles, it is possible to identify which position (e.g., left or right) two monitoring circuits 100b which are equidistant from management circuit 200b are each positioned at.

Control circuit 222, for example, measures the distance and angle of each slave (each monitoring circuit 100b) via IR-UWB communication in step S20 illustrated in FIG. 7.

In addition, control circuit 222, for example, rearranges slave IDs in order of distance and angle in step S30 illustrated in FIG. 7. Control circuit 222, for example, rearranges the items of identification information of monitoring circuits 100b in order of proximity and in ascending order of angle (from minus to plus). When there are two items of identification information of monitoring circuits 100b which are equidistant, control circuit 222 rearranges the two items of identification information by placing the one with the smaller angle (e.g., the one with a negative angle) at the top of the order and the one with the larger angle (e.g., the one with a positive angle) at the bottom of the order.

In addition, control circuit 222 generates a table (second table) indicating each slave ID and a serial position of battery pack 11 in step S40 illustrated in FIG. 7. Control circuit 222 generates a second table based on the table indicating the distance and angle information between a slave and a master (the table illustrated in FIG. 14A) and the items of identification information of monitoring circuits 100b that have been rearranged in step S30.

FIG. 14B is a diagram illustrating one example of the table (second table) in which a serial position and identification information of monitoring circuit 100b are associated with each other, according to the present variation. In the example of FIG. 14B, a MAC address is included as the identification information of monitoring circuit 100b.

As illustrated in FIG. 14B, according to the present variation, control circuit 222 generates a table in which a serial position and a MAC address of monitoring circuit 100b are associated with each other. The serial position is one example of information based on a measured value of TOF via IR-UWB communication, and the MAC address of monitoring circuit 100b is one example of identification information for use in communication in other wireless communication sections.

Control circuit 222, in step S40, calculates an angle between management circuit 200b and each of the plurality of monitoring circuits 100b based on a distance between management circuit 200b and each of the plurality of monitoring circuits 100b in each of the plurality of communication antennas, and generates a second table based on the angle that has been calculated. Specifically, control circuit 222, in step S40, generates the table illustrated in FIG. 14B, by associating one to one the serial positions indicated in FIG. 14A and the items of identification information of monitoring circuits 100b rearranged in order of distance and angle. When the items of identification information of monitoring circuits 100b are rearranged in order of proximity and in ascending order of angle (e.g., from a minus angle to a plus angle), control circuit 222 associates serial position “1(Lower)” with the identification information positioned at the top (“00-AA-BB-CC-DD-06” in the example of FIG. 14B; for example, the identification information of monitoring circuit 100b with the smallest distance and a negative angle). Next, control circuit 222 associates the serial position “2” with the identification information positioned at the second from the top (“00-AA-BB-CC-DD-02” in the example of FIG. 14B; for example, the identification information of monitoring circuit 100b with the smallest distance and a positive angle). Next, control circuit 222 associates the serial position “3” with the identification information positioned at the third from the top (“00-AA-BB-CC-DD-00” in the example of FIG. 14B; for example, the identification information of monitoring circuit 100b with the second smallest distance and a negative angle).

As described above, control circuit 222 generates the table illustrated in FIG. 14B, by sequentially associating the serial position with the identification information of monitoring circuit 100b. Stated differently, control circuit 222 generates a second table in which identification information of each monitoring circuit 100b and a serial position (positional information) are associated with each other, based on the distance and angle between management circuit 200b and each monitoring circuit 100b obtained by measurement using IR-UWB communication and the table illustrated in FIG. 14A.

Note that the table illustrated in FIG. 14B can be the same table as the table illustrated in FIG. 10B.

Control circuit 222 stores, in storage circuit 224, the table that has been generated in step S40 according to the present variation.

### Embodiment 3

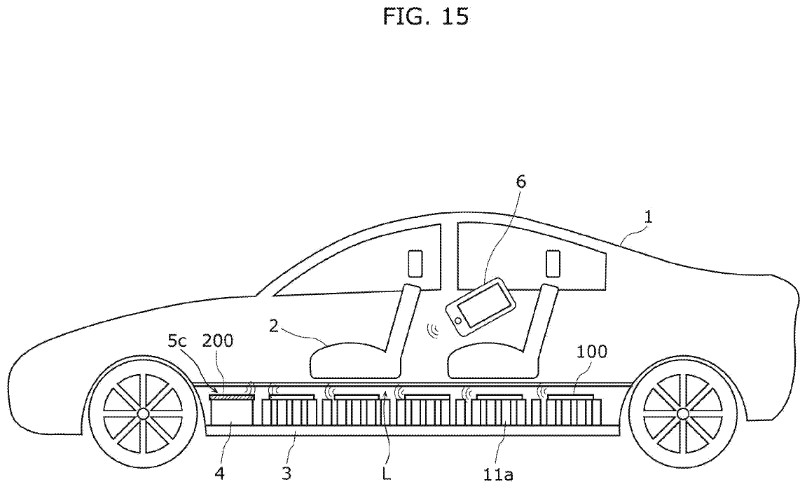

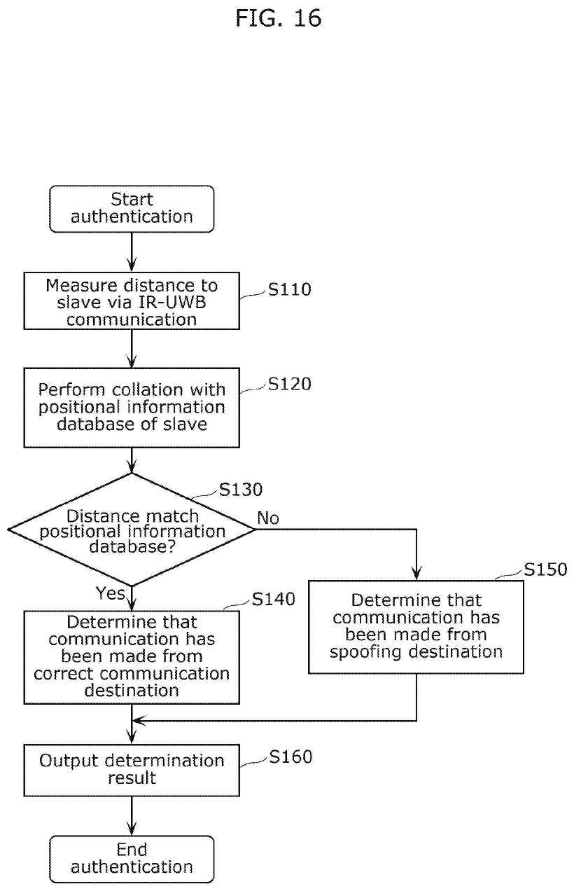

Hereinafter, a battery management system (BMS) according to the present embodiment will be described with reference to FIG. 15 and FIG. 16. Note that the following description focuses on the differences from Embodiment 1; explanations regarding points that are identical or similar to Embodiment 1 will be omitted or simplified. Each structural component of BMS according to the present embodiment may be identical to those of BMS 5 according to Embodiment 1, and the reference signs used in Embodiment 1 will be used for describing the respective structural components in the following description.

As described in Embodiment 1, cell stack 10 includes a plurality of battery packs 11, and monitoring circuits 100 are provided one-to-one to the plurality of battery packs 11. Management circuit 200 obtains data such as a voltage value of each battery cell 11a from corresponding monitoring circuit 100 to perform control on cell stack 10, but there is a possibility that the data is transmitted from an anomalous device. This could result in, for example, cell stack 10 being controlled from outside vehicle 1. In view of the above, the present embodiment describes a BMS capable of distinguishing between data transmitted from an anomalous device and data transmitted from monitoring circuit 100.

Note that an anomalous device may be a terminal device owned by a malicious user, or a terminal device that is remotely controlled through hacking and the like. The terminal device may be a mobile terminal such as a smartphone, or an in-vehicle device that has a function of communication such as a navigation system, and is fixed.

### [3-1. Configuration of Battery Management System]

First, a configuration of a battery management system will be described with reference to FIG. 15. FIG. 15 is a diagram schematically illustrating vehicle 1 provided with battery management system 5c (hereinafter also referred to as BMS 5c) according to the present embodiment and terminal device 6.

As illustrated in FIG. 15, BMS 5c is provided in vehicle 1. In vehicle 1, terminal device 6 is present in a state in which wireless communication can be carried out with BMS 5c (specifically, management circuit 200). It is assumed that terminal device 6 is being hacked, and data for fraudulently controlling BMS 5c is transmitted, for example, via BLE communication. Note that terminal device 6 may be present outside vehicle 1 as long as wireless communication with management circuit 200 is possible.

Terminal device 6, for example, is configured to be capable of performing BLE communication and IR-UWB communication.

At least one of measurement circuits 124 or 215 measures a distance between management circuit 200 and terminal device 6 via IR-UWB communication.

Control circuit 222 determines whether terminal device 6 is an anomalous device, based on the distance measured by measurement circuit 215 and a table generated in advance (e.g., the table indicated in FIG. 10A or FIG. 14A).

Storage circuit 224 stores the table including the distance between monitoring circuit 100 and management circuit 200.

### [3-2. Operation of Battery Management System]

Next, an operation of BMS 5c configured as described above will be described with reference to FIG. 16. FIG. 16 is a flowchart indicating the operation (control method) of BMS 5c according to the present embodiment. FIG. 16 illustrates an operation of authentication of received data performed by management circuit 200. Note that, it is assumed that the table indicated in FIG. 10A or FIG. 14A is stored in advance in storage circuit 224 of management circuit 200. In addition, control circuit 222 performs the processing indicated in FIG. 16 in both cases of receiving data from monitoring circuit 100 and receiving data from terminal device 6.

As illustrated in FIG. 16, control circuit 222 measures a distance of a slave via IR-UWB communication (S110). Control circuit 222 measures the distance between management circuit 200 and a device that has received data (e.g., terminal device 6 in the example of FIG. 15) via IR-UWB communication. The device includes monitoring circuit 100 and terminal device 6.

Next, control circuit 222 performs collation of the distance measured in step S110 with a positional information database of the slave (S120), and determines whether the distance that has been measured matches the positional information database (S130). When the distance (or distance and angle) measured in step S110 matches the distance included in the table illustrated in FIG. 10A (or distance and angle included in the table illustrated in FIG. 14A), control circuit 222 determines that the distance measured matches the positional information database.

Next, when it is determined that the distance measured matches the positional information database (Yes in S130), control circuit 222 determines that communication has been made from a correct communication destination (S140). When it is determined that the distance measured does not match the positional information database (No in S130), control circuit 222 determines that communication has been made from a spoofing destination (S150). Control circuit 222 determines whether the communication destination of the data received is a correct communication destination or a spoofing destination, based on a result of the collation.

Next, control circuit 222 outputs a determination result (S160). Control circuit 222 may, for example, output a determination result to a high-order system via CAN interface 223. In addition, when Yes determination has been made in step S140, control circuit 222 may store the data from the device into storage circuit 224, and control cell stack 10 based on this data. In addition, when No determination has been made in step S140, control circuit 222 stops or ignores (e.g., discards) the data from the device, and does not perform control of cell stack 10 based on this data (e.g., prohibits control of cell stack 10 based on this data). When terminal device 6 has been determined to be an anomalous device, control circuit 222 invalidates the communication with terminal device 6.

With such BMS 5c, it is possible to improve the security performance of vehicle 1. For example, it is possible to protect vehicle 1 from cyberattack.

Note that, the positional information database for use in determination may be a database including the distance measured in the BMS according to Embodiment 2 or the variation of Embodiment 2. For example, the processing indicated in FIG. 16 may be performed after the operation indicated in FIG. 7. For example, control circuit 222 controls each structural component such that TOF via IR-UWB communication is measured after pairing between monitoring circuit 100 and management circuit 200 by other wireless communication section.

### Other Embodiments

The battery management system according to one or more aspects have been described above based on the embodiments, etc. However, the present disclosure is not limited to the embodiments, etc. The present disclosure may include embodiments obtained by adding various changes envisioned by those skilled in the art to the embodiments and embodiments created by combining elements described in different embodiments as long as the resultant embodiments do not depart from the scope of the present disclosure.

An example in which the identification information of monitoring circuit 100 is transmitted to management circuit 200 via BLE communication has been described in the foregoing embodiments. However, for example, the identification information of monitoring circuit 100 may be transmitted to management circuit 200 via IR-UWB communication. In other words, data may be also transmitted from monitoring circuit 100 to management circuit 200 via IR-UWB communication.

In addition, in the variation of Embodiment 2 described above, each of the plurality of monitoring circuits and the management circuit may include three or more communication antennas for IR-UWB communication.

In addition, in Embodiment 2 and the variation of Embodiment 2 described above, at least one of: each of the plurality of monitoring circuits or the management circuit may include the measurement circuit for measuring TOF.

In addition, in the embodiments, etc., each structural component may be implemented as dedicated hardware or may be implemented by executing a software program suitable for the structural component. Each structural component may be implemented by a program executor, such as a CPU or a processor, reading out and executing the software program stored in a recording medium, such as a hardware disk or semiconductor memory.

Moreover, the order in which steps in a flowchart are performed is provided for specifically explaining the present disclosure, and the steps may be performed in a different order. Moreover, some of the steps may be performed with other steps simultaneously (in parallel), and some of the steps need not be performed.

Furthermore, the division of the functional blocks illustrated in the block diagrams has been presented as one example. Accordingly, a plurality of functional blocks may be implemented as one functional block, or one functional block may be divided into a plurality of functional blocks or a portion of the functions may be transferred to another functional block. In addition, functions of a plurality of functional blocks having similar functions may be processed by single hardware or software in parallel or in time division.

Moreover, each of the monitoring circuit and the management circuit according to the foregoing embodiments, etc. may be implemented as a single device or as a plurality of devices. When at least one of the monitoring circuit or the management circuit is implemented as a plurality of devices, each structural component included in the at least one circuit may be allocated to the plurality of devices in any manner. When the at least one circuit is implemented as a plurality of devices, the communication method between the plurality of devices is not particularly limited and may be wireless communication or wired communication. Moreover, wireless communication and wired communication may be combined as communication between devices.

In addition, each structural component described in the above embodiments, etc. may be implemented as software, or may be typically implemented as an LSI, which is an integrated circuit. These may be individually implemented as a single chip, or may be implemented as a single chip including some or all of them. Here, it is referred to as an LSI, but it may also be referred to as an IC, system LSI, super LSI, or ultra LSI depending on the degree of integration. Moreover, the method of integrated circuit implementation is not limited to an LSI, and may be implemented as a dedicated circuit (a general-purpose circuit that executes a dedicated program) or a general-purpose processor. A field programmable gate array (FPGA) that can be programmed after LSI manufacturing, or a reconfigurable processor that can reconfigure the connection or settings of circuit cells inside the LSI may also be used. Furthermore, if a technology for integrated circuit implementation emerges that replaces an LSI due to advancements in semiconductor technology or derivative technologies, it is natural to integrate the structural components using the technology.

A system LSI is an ultra-multifunctional LSI manufactured by integrating a plurality of processors on a single chip. Specifically, a system LSI is a computer system configured to include a microprocessor, read only memory (ROM), random access memory (RAM), and the like. A computer program is stored in the ROM. The system LSI achieves its function by the microprocessor operating according to the computer program.

In addition, one aspect of the present disclosure may be a computer program for causing a computer to perform characteristic steps included in the control method illustrated in FIG. 7 or 16.

In addition, the program may be a program for causing a computer to execute. Moreover, one aspect of the present disclosure may be a non-transitory computer-readable recording medium having recorded thereon such a program. For example, such a program may be recorded on a recording medium and distributed. For example, by installing a distributed program on a device including another processor and causing the processor to execute the program, it is possible to cause the device to perform each of the processes described above.

### Supplementary Notes

The following techniques are disclosed by the statements in the above embodiments, etc.

(Technique 1) A battery management system for managing a cell stack. The battery management system includes: a plurality of monitoring circuits that monitor the cell stack; and a management circuit that is connected to each of the plurality of monitoring circuits via wireless communication, and manages the cell stack. In the battery management system, at least one of the management circuit or each of the plurality of monitoring circuits includes a measurement circuit for measuring Time of Flight (TOF) between the management circuit and each of the plurality of monitoring circuits via impulse response ultra-wide band (IR-UWB) communication.

With this configuration, it is possible to calculate a distance between the management circuit and the plurality of monitoring circuits, by measuring TOF between the management circuit and the plurality of monitoring circuits. For example, it is possible to automatically identify a placement position of each of the plurality of monitoring circuits, based on the distance calculated. As a result, with the battery management system, it is possible to improve upon the above related art, in terms of readily obtaining the placement positions of the plurality of management circuits. (Technique 2) The battery management system according to Technique 1 further includes: a storage circuit that stores a first table in which (i) a distance between the management circuit and a position at which each of the plurality of monitoring circuits is disposed and (ii) positional information indicating a relative relationship between positions at which the plurality of monitoring circuits are disposed are associated with each other; and a control circuit that generates, based on the first table and a distance between the management circuit and each of the plurality of monitoring circuits obtained by measuring the TOF using the IR-UWB communication, a second table in which identification information of each of the plurality of monitoring circuits and the positional information are associated with each other.

With this configuration, it is possible to readily generate the second table, using the distance based on the TOF and the first table.

(Technique 3) The battery management system according to Technique 2, in which the management circuit includes a plurality of communication antennas for the IR-UWB communication.

With this configuration, it is possible to calculate, using trigonometry, a relative angle between the management circuit and the monitoring circuit. In other words, even when two ore more monitoring circuits with the same distance to the management circuit are present, it is possible to identify the respective placement positions of the two or more monitoring circuits.

(Technique 4) The battery management system according to Technique 3, in which the control circuit generates the second table based on (i) a distance between the management circuit and each of the plurality of monitoring circuits and (ii) a relative angle between the management circuit and each of the plurality of monitoring circuits, the distance and the relative angle being obtained using a corresponding one of the plurality of communication antennas.

In this manner, even when two ore more monitoring circuits with the same distance to the management circuit are present, it is possible to identify the respective placement positions of the two or more monitoring circuits.

(Technique 5) The battery management system according to any one of Techniques 2 to 4, in which each of the plurality of monitoring circuits and the management circuit include a UWB communication section that performs the IR-UWB communication, and an other wireless communication section that performs communication different from the IR-UWB communication, and the identification information of each of the plurality of monitoring circuits is identification information that is used in communication performed by the other wireless communication section in each of the plurality of monitoring circuits.

With this configuration, it is possible to utilize the identification information that is used in communication performed by the other wireless communication section; that is, communication different from the IR-UWB communication, and thus it is not necessary to set unique identification information. As a result, it is possible to reduce the processing amount in the battery management system.

(Technique 6) The battery management system according to Technique 5, in which the identification information is a media access control (MAC) address.

With this configuration, it is possible to use the MAC address as the identification information. The MAC address is uniquely set for each monitoring circuit, and thus the plurality of monitoring circuits are readily identified.

(Technique 7) The battery management system according to any one of Techniques 1 to 6, in which the plurality of monitoring circuits are arranged at mutually different distances from the management circuit.

With this configuration, it is possible to identify a placement position of a monitoring circuit, by only calculating the distance between the monitoring circuit and the management circuit.

(Technique 8) A battery management system for managing a cell stack. The battery management system includes: a monitoring circuit that monitors the cell stack; a management circuit that is connected to the monitoring circuit via impulse response ultra-wide band (IR-UWB) communication, and manages the cell stack; a storage circuit that stores a table including a distance between the monitoring circuit and the management circuit; a measurement circuit that measures Time of Flight (TOF) between the management circuit and a terminal device of a communication source via the IR-UWB communication; and a control circuit that detects whether the terminal device is an anomalous device, based on the table and information based on the TOF measured by the measurement circuit.

With this configuration, it is possible determine whether the terminal device is an anomalous device, by using the distance between the management circuit and the terminal device obtained via IR-UWB communication. For example, when an anomalous terminal device is spoofing as a monitoring circuit and performing communication with the management circuit, it is possible to detect the anomalous terminal device. As a result, with the battery management system, it is possible to improve upon the above related art, in terms of improving the security performance.

(Technique 9) The battery management system according to Technique 8, in which the control circuit invalidates communication with the terminal device when the terminal device has been determined to be an anomalous device.

In this manner, it is possible to inhibit the management circuit from controlling the cell stack based on the information from the anomalous terminal device.

(Technique 10) The battery management system according to Technique 8 or 9, in which the monitoring circuit and the management circuit each include a UWB communication section that performs the IR-UWB communication and an other wireless communication section that performs communication different from the IR-UWB communication, and the table includes information in which information based on the TOF and identification information that is used in communication performed by the other wireless communication section are associated with each other.

With this configuration, it is possible to improve the security performance of the BMS, using the table that utilizes the identification information used in communication performed by the other wireless communication section; that is, communication different from the IR-UWB communication.

(Technique 11) The battery management system according to Technique 10, in which the control circuit performs control in which the TOF is measured via the IR-UWB communication after pairing between the monitoring circuit and the management circuit performed by the other wireless communication section.

In this manner, the management circuit is capable of obtaining the identification information of the monitoring circuit before measuring the TOF. For example, when generating a table in which a relative position and identification information of a monitoring circuit are associated with each other, it is possible to readily generate the table. s

(Technique 12) The battery management system according to any one of Techniques 1 to 11 further includes the cell stack.

With this configuration, the battery management system including the cell stack is capable of improve upon the above related art.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is useful for battery management systems provided in vehicles.

1.
A battery management system for managing a cell stack, the battery management system comprising:
a plurality of monitoring circuits that monitor the cell stack; and
a management circuit that is connected to each of the plurality of monitoring circuits via wireless communication, and manages the cell stack, wherein
at least one of the management circuit or each of the plurality of monitoring circuits includes a measurement circuit for measuring Time of Flight (TOF) between the management circuit and each of the plurality of monitoring circuits via impulse response ultra-wide band (IR-UWB) communication.

2. The battery management system according to claim 1, further comprising:
a storage circuit that stores a first table in which (i) a distance between the management circuit and a position at which each of the plurality of monitoring circuits is disposed and (ii) positional information indicating a relative relationship between positions at which the plurality of monitoring circuits are disposed are associated with each other; and
a control circuit that generates, based on the first table and a distance between the management circuit and each of the plurality of monitoring circuits obtained by measuring the TOF using the IR-UWB communication, a second table in which identification information of each of the plurality of monitoring circuits and the positional information are associated with each other.

3. The battery management system according to claim 2, wherein
the management circuit includes a plurality of communication antennas for the IR-UWB communication.

4. The battery management system according to claim 3, wherein
the control circuit generates the second table based on (i) a distance between the management circuit and each of the plurality of monitoring circuits and (ii) a relative angle between the management circuit and each of the plurality of monitoring circuits, the distance and the relative angle being obtained using a corresponding one of the plurality of communication antennas.

5. The battery management system according to claim 2, wherein
each of the plurality of monitoring circuits and the management circuit include a UWB communication section that performs the IR-UWB communication, and an other wireless communication section that performs communication different from the IR-UWB communication, and
the identification information of each of the plurality of monitoring circuits is identification information that is used in communication performed by the other wireless communication section in each of the plurality of monitoring circuits.

6. The battery management system according to claim 5, wherein
the identification information is a media access control (MAC) address.

7. The battery management system according to claim 1, wherein
the plurality of monitoring circuits are arranged at mutually different distances from the management circuit.

8. A battery management system for managing a cell stack, the battery management system comprising:
a monitoring circuit that monitors the cell stack;
a management circuit that is connected to the monitoring circuit via impulse response ultra-wide band (IR-UWB) communication, and manages the cell stack;
a storage circuit that stores a table including a distance between the monitoring circuit and the management circuit;
a measurement circuit that measures Time of Flight (TOF) between the management circuit and a terminal device of a communication source via the IR-UWB communication; and
a control circuit that detects whether the terminal device is an anomalous device, based on the table and information based on the TOF measured by the measurement circuit.

9. The battery management system according to claim 8, wherein
the control circuit invalidates communication with the terminal device when the terminal device has been determined to be an anomalous device.

10. The battery management system according to claim 8, wherein
the monitoring circuit and the management circuit each include a UWB communication section that performs the IR-UWB communication and an other wireless communication section that performs communication different from the IR-UWB communication, and
the table includes information in which information based on the TOF and identification information that is used in communication performed by the other wireless communication section are associated with each other.

11. The battery management system according to claim 10, wherein
the control circuit performs control in which the TOF is measured via the IR-UWB communication after pairing between the monitoring circuit and the management circuit performed by the other wireless communication section.

12. The battery management system according to claim 1, further comprising:
the cell stack.
